(19) United States
(12) Patent Application Publication
(10) Pub. No.: US 2025/0040418 A1
(43) Pub. Date: Jan. 30, 2025

(54) DISPLAY PANEL AND DISPLAY DEVICE

(71) Applicant: HKC CORPORATION LIMITED, Shenzhen (CN)

(72) Inventors: JING LI, Shenzhen (CN); Hailiang Wang, Shenzhen (CN); Ting Zhou, Shenzhen (CN); Laidi Wu, Shenzhen (CN); Min Huang, Shenzhen (CN); Tianjun Huang, Shenzhen (CN); Haijiang Yuan, Shenzhen (CN)

(21) Appl. No.: 18/747,440

(22) Filed: Jun. 19, 2024

(30) Foreign Application Priority Data
Jul. 28, 2023 (CN) 202310948071.3

(51) Int. Cl. H10K 59/80; H10K 59/122

(52) U.S. Cl. CPC H10K 59/8792; H10K 59/122

(57) ABSTRACT

A display panel and a display device are disclosed. The display panel includes a substrate, a light-emitting element layer, a pixel defining layer, an encapsulation layer, a color filter layer, and an anti-reflection layer. The light-emitting element layer includes multiple light-emitting elements arranged in an array on the substrate. The pixel defining layer is disposed on the substrate, and every two adjacent light-emitting elements are separated by the pixel defining layer. The encapsulation layer is disposed on the light-emitting elements and the pixel defining layer. The color filter layer includes multiple color filters disposed on the encapsulation layer. The anti-reflection layer is disposed on the encapsulation layer to block external light from entering the display panel, and includes an alignment film and polarizing molecules evenly distributed within the alignment film. The polarizing molecules are arranged in two mutually perpendicular orientations or in a unidirectional orientation in the alignment film.

### CROSS-REFERENCE TO RELATED APPLICATIONS

This application claims the priority and benefit of Chinese patent application number 2023109480713, titled “Display Panel and Display Device” and filed Jul. 28, 2023 with China National Intellectual Property Administration, the entire contents of which are incorporated herein by reference.

### TECHNICAL FIELD

This application relates to the field of display technology, and in particular, to a display panel and a display device.

### BACKGROUND

The description provided in this section is intended for the mere purpose of providing background information related to the present application but doesn't necessarily constitute prior art.

With the continuous development of OLED (Organic Light-Emitting Diode) display technology, OLED is increasingly used in displays such as smartphones, tablets, computers, and TVs. OLED displays have the advantages of thinness and light weight, high contrast, fast response, wide viewing angle, high brightness, full-color, etc. In order to reduce the reflectivity of external light in an OLED display, the current mainstream solution is to attach a circular polarizer to a light-emitting surface of the OLED display. However, this solution reduces the light-emitting effect due to the relatively great light loss of the circular polarizer. Another solution is to dispose a color filter on the light-emitting surface of the OLED display, also known as a COE (Color filter on Encapsulation) display panel, to improve the light-emitting efficiency through the color filter.

However, due to the structure of the COE display panel, the ambient reflected light is stronger than that of the display panel equipped with a polarizer, which easily causes problems such as glare. In this regard, those having ordinary skill in the art urgently need a solution that can solve the problem of ambient light reflection.

### SUMMARY

In view of the above, it is one purpose of this application to provide a display panel and a display device to improve the phenomenon of ambient light reflection without affecting the light-emitting efficiency.

This application discloses a display panel, including a substrate, a light-emitting element layer, a pixel defining layer, an encapsulation layer, a color filter layer, and an anti-reflection layer. The light-emitting element layer includes a plurality of light-emitting elements. The plurality of light-emitting elements are disposed in an array on the substrate. The pixel defining layer is disposed on the substrate, and every two adjacent light-emitting elements are separated by the pixel defining layer. The encapsulation layer is disposed on the light-emitting elements and the pixel defining layer. The color filter layer includes a plurality of color filters disposed on the encapsulation layer. The anti-reflection layer is disposed on the encapsulation layer to block external light from entering the display panel. The anti-reflection layer includes an alignment film and polarizing molecules evenly distributed within the alignment film. The polarizing molecules are arranged in mutually perpendicular orientations or arranged in a unidirectional orientation in the alignment film.

In some embodiments, the display panel includes an opening region and a non-opening region. The pixel defining layer is disposed in the non-opening region. The light-emitting element layer is arranged in the opening region. The anti-reflection layer includes a light-shielding piece, and the light-shielding piece is disposed in the non-opening region corresponding to the pixel defining layer. The polarizing molecules in the light-shielding piece are aligned in mutually perpendicular orientations to form a mutually-perpendicular arrangement. The light-shielding piece is used to shield light.

In some embodiments, the light-shielding piece and the color filter are disposed in a same layer, and adjacent color filters are separated by the light-shielding piece.

In some embodiments, the display panel includes an opening region and a non-opening region. The pixel defining layer is disposed in the non-opening region. The light-emitting element layer is arranged in the opening region. The anti-reflection layer includes a semi-shielding piece, and the semi-shielding piece is arranged corresponding to the opening region. The polarizing molecules in the half-shielded part adopt unidirectional alignment to form a unidirectional directional arrangement. The semi-shielding piece is used to pass through part of the outgoing light and block incident light from the outside.

In some embodiments, the plurality of light-emitting elements include a plurality of white light-emitting elements and a plurality of first light-emitting elements. An orthographic projection of the semi-shielding piece on the substrate overlap an orthographic projection of the white light-emitting element on the substrate. The plurality of color filters are arranged in one-to-one correspondence to the plurality of first light-emitting elements. The plurality of first light-emitting elements include at least two light-emitting elements with different colors.

In some embodiments, the display panel includes an opening region and a non-opening region. The pixel defining layer is disposed in the non-opening region. The light-emitting element layer is arranged in the opening region. The anti-reflection layer includes a light-shielding piece and a semi-shielding piece. The light-shielding piece is arranged in the non-opening region corresponding to the pixel defining layer, and the light-shielding piece uses an arrangement with mutually perpendicular orientations. The semi-shielding piece is arranged corresponding to the opening region, and the semi-shielding piece is arranged in a unidirectional orientation. The plurality of light-emitting elements include a plurality of white light-emitting elements and a plurality of first light-emitting elements. An orthographic projection of the semi-shielding piece on the substrate overlaps an orthographic projection of the white light-emitting element on the substrate. The plurality of the color filters are arranged in one-to-one correspondence with a plurality of the first light-emitting elements. The plurality of first light-emitting elements include at least two light-emitting elements with different colors.

In some embodiments, the light-shielding piece and the semi-shielding piece are formed using the same process. The thickness of the light-shielding piece is the same as that of the semi-shielding piece. The light-shielding piece, the semi-shielding piece, and the color filter are disposed in the same layer.

In some embodiments, the anti-reflection layer is disposed on the color filter layer.

In some embodiments, a concentration of polarizing molecules in the alignment film is no more than 20%.

This application further discloses a display device, including a driving circuit and the above-mentioned display panel, wherein the driving circuit is used to drive the display panel to display.

In this application, the alignment film is used and the polarizing molecules are arranged in the alignment film, and the polarizing molecules are arranged in an oriented manner to absorb the incident light from the outside world and prevent external incident light from entering the display panel and causing some of the film layers in the display panel to reflect the incident light, causing problems such as glare. In addition, the present application may provide an anti-reflection layer in a local area, and use the anti-reflection layer to improve the phenomenon of ambient light reflection without reducing the brightness and display effect. The anti-reflection layer of the present application is formed by an alignment film and polarizing molecules, and has a simple structure, simple manufacturing process, and low cost. In particular, the manufacturing process of the alignment film is mature, and there will be no problems such as film defects between the alignment film and other film layers such as the color filter layer.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principle of the present application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic diagram of a display panel according to a first embodiment of the present application.

FIG. 2 is a schematic diagram of a semi-shielding piece of an anti-reflection layer according to the present application.

FIG. 3 is a schematic diagram of a light-shielding piece of an anti-reflection layer according to the present application.

FIG. 4 is a schematic diagram of a display panel according to a second embodiment of the present application.

FIG. 5 is a schematic diagram of a display panel according to a third embodiment of the present application.

FIG. 6 is a schematic diagram of another display panel according to the third embodiment of the present application.

FIG. 7 is a schematic diagram of a display panel according to a fourth embodiment of the present application.

FIG. 8 is a schematic diagram of a display device according to a fifth embodiment of the present application.

In the drawings: 100, display panel; 101, opening region; 102, non-opening region; 110, substrate; 120, light-emitting element layer; 121, light-emitting element; 122, first light-emitting element; WLED, white light-emitting element; 123, bottom electrode; 124, light-emitting layer; 125, top electrode; 130, pixel defining layer; 140, encapsulation layer; 150, color filter layer; 151, color filter; R, red filter; G, green filter; B, blue filter; 160, anti-reflection layer; 161, alignment film; 162, polarizing molecule; 163, light-shielding piece; 164, semi-shielding piece; 170, thin film transistor layer.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

Hereinafter this application will be described in further detail with reference to the accompanying drawings and some optional embodiments.

### Embodiment 1

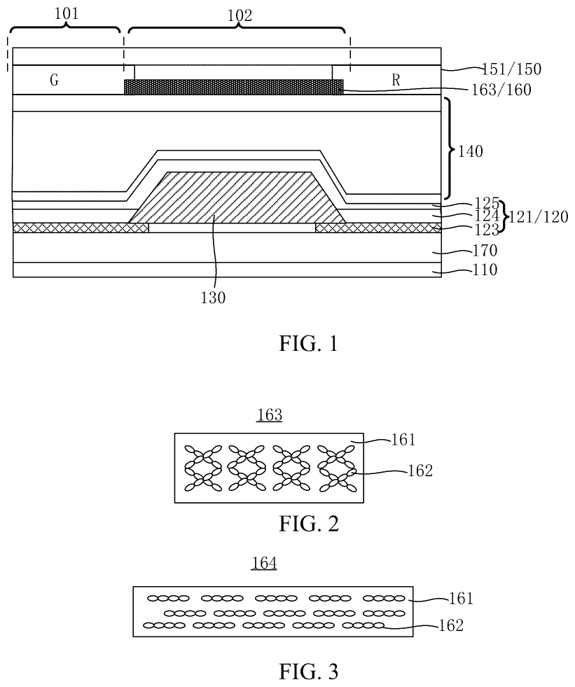

FIG. 1 is a schematic diagram of a display panel according to a first embodiment of the present application. As shown in FIG. 1, the display panel 100 includes a substrate 110, a light-emitting element layer 120, a pixel defining layer 130, an encapsulation layer 140, a color filter layer 150, and an anti-reflection layer 160.

The light-emitting element layer 120 includes a plurality of light-emitting elements 121, and the plurality of light-emitting elements 121 are arranged in an array on the substrate 110. The pixel defining layer 130 is disposed on the substrate 110, and every two adjacent light-emitting elements 121 are separated by the pixel defining layer 130. The encapsulation layer 140 is disposed on the light-emitting elements 121 and the pixel defining layer 130. The color filter layer 150 includes a plurality of color filters 151 disposed on the encapsulation layer 140. The anti-reflection layer 160 is disposed on the encapsulation layer 140 to prevent external light from entering the display panel 100. The anti-reflection layer 160 includes an alignment film 161 and polarizing molecules 162 uniformly distributed in the alignment film 161. The polarizing molecules 162 are aligned in two mutually perpendicular orientations and/or aligned in a unidirectional orientation in the alignment film 161.

This application uses the alignment film 161 and the polarizing molecules 162 disposed in the alignment film 161 to achieve the absorption of incident light from the outside by orienting the polarizing molecules 162, thus preventing external incident light from entering the display panel 100 which may cause some of the film layers in the display panel 100 to reflect the incident light hence leading to problems such as glare. Furthermore, in this application, the anti-reflection layer 160 may be disposed in a local area at the position of the color filter layer 150, so that the anti-reflection layer 160 may be used to improve the phenomenon of ambient light reflection without reducing the brightness and display effect. The anti-reflection layer 160 of the present application is formed by an alignment film 161 and polarizing molecules 162, and has a simple structure, simple manufacturing process, and low cost. In particular, the manufacturing process of the alignment film 161 is mature, and there will be no problems such as film defects between the alignment film 161 and other film layers such as the color filter layer 150.

In the OLED display panel 100, in the exemplary technology, either COE technology or polarizer technology is used. In this application, the high transmittance solution of the COE technology and the anti-reflection solution in the polarizer are combined, so that a technical solution of regional and local polarization is proposed based on the structure of the COE display panel 100.

It may be understood that in this embodiment, the polarizing molecules 162 are molecules with polarizing effects, such as iodine dye molecules, which have light-absorbing properties when aligned. The alignment film 161 is made of a resin material and has a transparent state. This application creates light absorption characteristics by orderly arranging the polarizing molecules 162 in the alignment film 161.

The anti-reflection layer 160 includes at least three states: opaque, transparent, and semi-transparent.

FIG. 2 is a schematic diagram of a semi-shielding piece of an anti-reflection layer according to the present application. As shown in FIG. 2, when the polarizing molecules 162 in the anti-reflection layer 160 are aligned in a unidirectional orientation, the polarizing molecules 162 in the alignment film 161 are aligned in a single unidirectional orientation and have a semi-transparent state. When arranged in a unidirectional orientation, the polarizing molecules 162 are similar to slits in a polarizer, forming a polarizing effect that prevents part of the ambient light from entering, thereby reducing reflection. In a specific process, the alignment film 161 may be illuminated along one direction, so that the alignment film 161 has an alignment force in one direction, thereby forming unidirectionally oriented polarizing molecules 162. In particular, the alignment force only needs to be perpendicular to a normal direction of the display panel 100.

FIG. 3 is a schematic diagram of a light-shielding piece of an anti-reflection layer of according to the present application. Referring to FIG. 3, when the polarizing molecules 162 of the anti-reflection layer 160 have a bidirectional arrangement, they may be arranged in mutually perpendicular orientations. At this time, when the polarizing molecules 162 in the alignment film 161 are arranged in two orientations and are perpendicular to each other, they are similar to two polarizing layers with perpendicular absorption axes, and thus have a superior light-shielding effect. The light-shielding effect can reach more than 99.95%. The mutually perpendicularly oriented polarizing molecules 162 form mutually perpendicular alignments through alignment forces in two perpendicular orientations, based on illumination with an alignment direction of a and illumination of a+90°. This a is perpendicular to the normal direction of the display panel 100.

When the anti-reflection layer 160 is set to a hollowed-out state, it is completely transparent.

In particular, the concentration of polarizing molecules 162 in the alignment film 161 is no more than 20%. In this application, the light-shielding or semi-transparent effect is mainly achieved through the directional arrangement of the polarizing molecules 162, and it is not necessary for the polarizing molecules 162 to completely fill the alignment film 161. By adjusting the arrangement of the polarizing molecules 162, the semi-transparent and opaque states are achieved.

In this embodiment, the light-emitting elements 121 emit light after passing through each color filter 151. Each light-emitting element 121 is controlled by a corresponding thin film transistor to achieve controllable brightness of each sub-pixel. In particular, a thin film transistor layer 170 is disposed below the light-emitting element layer 120 and the pixel defining layer 130, and each light-emitting element 121 is separately controlled by providing an array of thin film transistors.

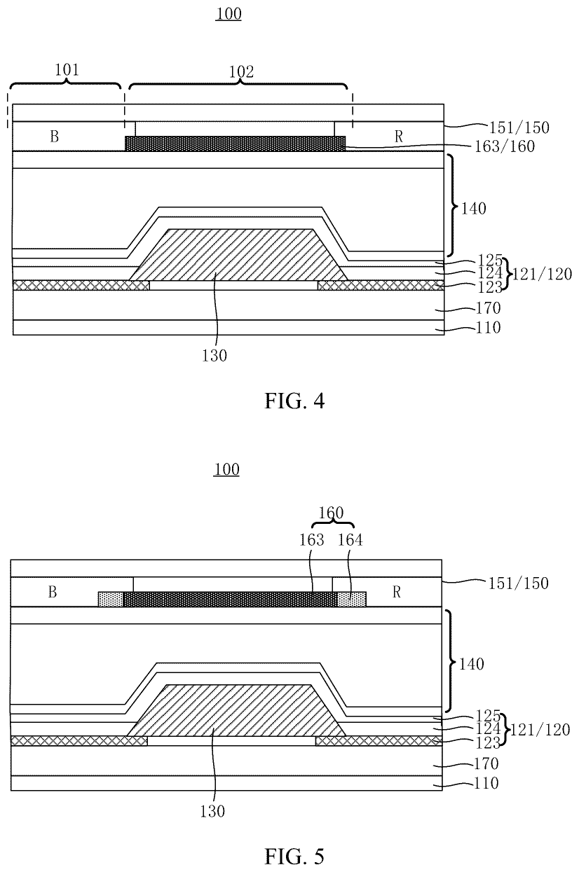

FIG. 4 is a schematic diagram of a display panel according to a second embodiment of the present application. As shown in FIG. 4, the display panel 100 includes a substrate 110, a light-emitting element layer 120, a pixel defining layer 130, an encapsulation layer 140, a color filter layer 150, and an anti-reflection layer 160. It may be understood that the substrate 110, the light-emitting element layer 120, the pixel defining layer 130, the encapsulation layer 140, the color filter layer 150, and the anti-reflection layer 160 may be configured the same as those in Embodiment 1 unless otherwise specified.

### Embodiment 2

The color filter layer 150 includes a plurality of color filters 151 disposed on the encapsulation layer 140. The anti-reflection layer 160 is disposed on the encapsulation layer 140 to block external light from entering the display panel 100. The anti-reflection layer 160 includes an alignment film 161 and polarizing molecules 162 evenly distributed in the alignment film 161. The polarizing molecules 162 are aligned to be mutually perpendicular to each other in the alignment film 161.

The display panel 100 includes an opening region 101 and a non-opening region 102. The pixel defining layer 130 is disposed in the non-opening region 102, and the light-emitting element layer 120 is disposed in the opening region 101. The anti-reflection layer 160 includes a light-shielding piece 163, and the light-shielding piece 163 is disposed in the non-opening region 102 corresponding to the pixel defining layer 130. The polarizing molecules 162 in the light-shielding piece 163 are mutually perpendicularly aligned to form a mutually perpendicular arrangement, and the light-shielding piece 163 is used for light-shielding.

In this application, the black matrix in the color filter layer 150 may be replaced by providing the anti-reflection layer 160. In this embodiment, all polarizing molecules 162 in the light-shielding piece 163 may be arranged in two mutually perpendicular orientations to replace the black matrix in the display panel 100.

The display panel 100 includes an opening region 101 and a non-opening region 102. The opening region 101 may refer to the position of the color filter 151, an area that can display colors such as red, green, and blue during display, and roughly corresponds to the area between adjacent pixel defining layers 130 of the display panel 100. The non-opening region 102 is the position of the black matrix, which is displayed as a black area during display, roughly corresponding to the area of the pixel defining layer 130. Both the opening region 101 and the non-opening region 102 may be located in the display area of the display panel 100.

In particular, the light-shielding pieces 163 and the color filters 151 are disposed in the same layer, and adjacent color filters 151 are separated by the respective light-shielding piece 163.

In this embodiment, the light-shielding piece 163 is located in the non-opening region 102, and its main function is to block light from the non-opening region 102 of the display panel 100, and is also used to avoid color mixing between adjacent sub-pixels. In particular, the film layer between the alignment film 161 and the color filter 151 has few defects. At present, in a low-temperature black matrix mainly made of carbon black material, the low temperature is 80 degrees. Film layer problems are likely to occur between the black matrix and the color filter 151, resulting in display defects of the display panel 100. This embodiment uses an alignment film 161 and mutually perpendicularly oriented polarizing molecules 162 inside the alignment film 161 to achieve light shielding and solve the film layer problem, with a simple process and low cost.

The light-emitting element 121 in an OLED display panel 100 may include a bottom electrode 123, a light-emitting layer 124, and a top electrode 125 that are stacked in sequence in a direction facing away from the substrate 110. The bottom electrode 123 may use a metal electrode as the anode of the light-emitting element 121. Of course, there is also a composite electrode using a stack of a transparent conductive layer and a metal electrode as the anode. The top electrode 125 may use a transparent conductive layer as the cathode of the light-emitting element 121. Since the bottom electrode 123 has high reflective properties, when driven by a certain voltage, electrons and holes move from the cathode and anode to the light-emitting layer 124 respectively and recombine to emit visible light. Therefore, the light-emitting element 121 may emit light in one direction, such as a bottom-emitting light-emitting element 121. There is also a top-emitting light-emitting element 121, which switch the anode and cathode materials to form light emitted from top to bottom.

However, when the light-emitting element 121 does not emit light, external ambient light enters the surface. Because the ambient light may include the entire visible light band or a wide spectrum band, the color filter 151 may filter out most of the wavelength bands of the ambient light. After natural light (white light) passes through the color filter 151, only the light of the corresponding color is transmitted, and the light in other wavelength bands will be absorbed by the color filter 151. For example, the red filter may only transmit red light. After the red light enters the light-emitting element 121, since the metal electrode has a relatively high reflectivity, the red light is reflected and emitted from the red filter or from other pixel positions, causing glare or color shift. In this application, by providing the light-shielding piece 163, most of the reflected light is absorbed.

The light-emitting element 121 in this embodiment includes a red light-emitting element 121, a green light-emitting element 121, and a blue light-emitting element 121. The red light-emitting element 121, the green light-emitting element 121, and the blue light-emitting element 121 are arranged in an array. The effective light-emitting area of the light-emitting element 121 is the anode disposed between the pixel defining layers 130, which emits light by exciting the light-emitting layer 124. The area where the anode is blocked by the pixel defining layer 130 does not actually emit light. The display panel 100 in this embodiment is an OLED display panel 100 using the RGB light-emitting elements 121 as the light sources. Of course, the light-emitting elements 121 in this application may also be a white light-emitting element to form the OLED display panel 100 using white light as the light source.

The color filters 151 include a red filter R, a green filter G, and a blue filter B. When the light-emitting elements 121 of the display panel 100 are RGB light-emitting elements 121, the red filter R is disposed corresponding to the red light-emitting element 121, the green filter G is disposed corresponding to the green light-emitting element 121, and the blue filter B is disposed corresponding to the blue light-emitting element 121. When the display panel 100 uses white light-emitting elements, then the red filters R, the green filters G, and the blue filters B are arranged in an array.

The encapsulation layer 140 includes multiple layers of alternating organic encapsulation layers 140 and inorganic encapsulation layers 140. It may include at least two inorganic encapsulation layers 140 and an organic encapsulation layer 140 disposed between the two inorganic encapsulation layers 140 to encapsulate the light-emitting element layer 120.

In particular, the thickness of the alignment film 161 may be about 100 nm, while the thickness of the color filter 151 may reach 2 μm. In the above embodiment, if the light-shielding pieces 163 and the color filters 151 are disposed in the same layer, a planarization layer needs to be used to fill the unevenness between the light-shielding piece 163 and the color filter 151, or a thickened alignment film 161 may be used.

In another embodiment, the light-shielding piece 163 is disposed on the color filter 151. Considering that the alignment film 161 is relatively thin, it can be directly formed on or below the color filter layer 150.

### Embodiment 3

FIG. 5 is a schematic diagram of a display panel according to a third embodiment of the present application. As shown in FIG. 5, the display panel 100 includes a substrate 110, a light-emitting element layer 120, a pixel defining layer 130, an encapsulation layer 140, a color filter layer 150, and an anti-reflection layer 160. It may be understood that the substrate 110, the light-emitting element layer 120, the pixel defining layer 130, the encapsulation layer 140, the color filter layer 150, and the anti-reflection layer 160 may be configured the same as those in Embodiment 1 unless otherwise specified.

The color filter layer 150 includes a plurality of color filters 151 disposed on the encapsulation layer 140. The anti-reflection layer 160 is disposed on the encapsulation layer 140 to block external light from entering the display panel 100. The anti-reflection layer 160 includes an alignment film 161 and polarizing molecules 162 evenly distributed in the alignment film 161. The polarizing molecules 162 are unidirectionally aligned in the alignment film 161.

The display panel 100 includes an opening region 101 and a non-opening region 102. The pixel defining layer 130 is disposed in the non-opening region 102. The light-emitting element layer 120 is disposed in the opening region 101. The anti-reflection layer 160 includes a semi-shielding piece 164, which is disposed corresponding to the opening region 101. The polarizing molecules 162 of the semi-shielding piece 164 are unidirectionally aligned to form a unidirectional directional arrangement. The semi-shielding piece 164 is used to transmit part of the outgoing light and block incident light from the outside.

In this application, by providing the semi-shielding piece 164, part of the non-shielding layer, for example, the film layer(s) above the white sub-pixel, can be replaced. For example, replacing the film layers on the red filter R, the green filter G, and the blue filter B, most of the ambient light is filtered through the semi-shielding piece 164.

In one embodiment, the semi-shielding piece 164 is annular and is arranged around the color filter 151 to reduce ambient light reflection mainly by filtering ambient light around the color filter 151. The area of the semi-shielding piece 164 does not exceed one quarter of the area of the corresponding color filter 151. In this embodiment, the light intensity around the color filter 151 is slightly reduced, but this brings about the effect of lower ambient light reflection of the color filter 151. For this embodiment, a black matrix may be provided between the color filters 151 for light shielding, or the above-mentioned light-shielding pieces 163 may be provided for light shielding.

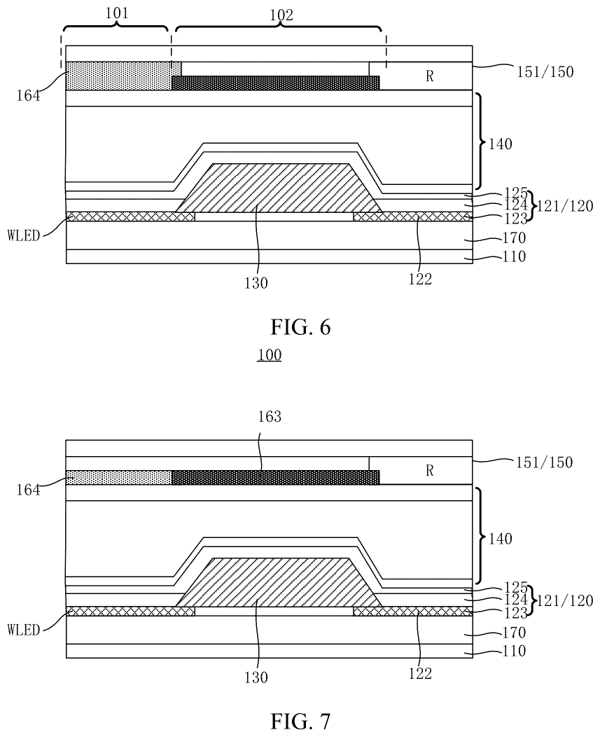

FIG. 6 is a schematic diagram of another display panel according to the third embodiment of the present application. Referring to FIG. 6, in another embodiment, the plurality of light-emitting elements 121 include a plurality of white light-emitting elements WLED and a plurality of first light-emitting elements 122. An orthographic projection of the semi-shielding piece 164 on the substrate 110 overlaps an orthographic projection of the white light-emitting element WLED on the substrate 110. The plurality of color filters 151 are arranged in one-to-one correspondence with the plurality of first light-emitting elements 122. The plurality of first light-emitting elements 122 include at least two light-emitting elements 121 with different colors.

That is, the first light-emitting elements 122 include a first red light-emitting element 121, a first green light-emitting element 121, and a first blue light-emitting element 121. Each pixel includes at least a first red light-emitting element 121, a first green light-emitting element 121, a first blue light-emitting element 121, and a white light-emitting element WLED to form the RGBW display panel 100.

In a display panel 100 of the COE architecture, if it is an RGBW pixel architecture, the white sub-pixels tend to have more ambient light reflection than the red, green and blue sub-pixels. In this application, by arranging the semi-shielding piece 164 on the white sub-pixel, although part of the emitted light of the white sub-pixel is lost and the brightness of the white sub-pixel is reduced, when the display panel 100 is in a dark state or some display area is in a dark state, most of the ambient light is filtered by the semi-shielding piece 164 and cannot enter the interior of the display panel 100 from the white sub-pixel area. This prevents ambient light from entering the interior of the display panel 100, being reflected single or multiple times by the various film layer, and emitting from the non-light-emitting display area, causing problems such as reflection and glare.

This embodiment is suitable for the RGBW display panel 100 and can mainly solve the reflection problem in the white sub-pixel area.

It can be understood that the above-mentioned solution where the semi-shielding piece 164 is arranged around the color filter 151 and the solution where it is arranged in the white sub-pixel may be combined. Accordingly, on the one hand, the problem of ambient light reflection of the display panel 100 in the dark state is improved, and on the other hand, the display effect of the display panel 100 is improved.

### Embodiment 4

FIG. 7 is a schematic diagram of a display panel according to a fourth embodiment of the present application. As shown in FIG. 7, the display panel 100 includes a substrate 110, a light-emitting element layer 120, a pixel defining layer 130, an encapsulation layer 140, a color filter layer 150, and an anti-reflection layer 160. The color filter layer 150 includes a plurality of color filters 151 disposed on the encapsulation layer 140. The anti-reflection layer 160 is disposed on the encapsulation layer 140 to block external light from entering the display panel 100. The anti-reflection layer 160 includes an alignment film 161 and polarizing molecules 162 evenly distributed in the alignment film 161. The anti-reflection layer 160 includes a semi-shielding piece 164 and a light-shielding piece 163. The light-shielding piece 163 is disposed in the non-opening region 102 corresponding to the pixel defining layer 130. The light-shielding piece 163 uses a mutually perpendicular arrangement. The semi-shielding piece 164 is disposed corresponding to the opening region 101. The semi-shielding piece 164 is arranged in a unidirectional direction.

The plurality of light-emitting elements 121 include a plurality of white light-emitting elements WLED and a plurality of first light-emitting elements 122. An orthographic projection of the semi-shielding piece 164 on the substrate 110 overlaps the orthographic projection of the white light-emitting element WLED on the substrate 110. The plurality of color filters 151 are arranged in one-to-one correspondence with the plurality of first light-emitting elements 122. The plurality of first light-emitting elements 122 include at least two light-emitting elements 121 with different colors.

In this embodiment, the semi-shielding piece 164 is arranged corresponding to the white sub-pixel, and the light-shielding piece 163 is arranged corresponding to the non-opening region 102. In this application, the light-shielding piece 163 is disposed in the area that needs to be light-shielded, and the semi-shielding piece 164 is disposed at the position of the white sub-pixel. This embodiment can effectively improve the light-emitting efficiency of the opening region 101 of the RGB pixels. The process flow is simple, which is beneficial to improving the yield and visual quality, and also brings the advantage of reducing costs.

The light-shielding piece 163 and the semi-shielding piece 164 are formed using the same manufacturing procedure. The thickness of the light-shielding piece 163 is the same as that of the semi-shielding piece 164. The light-shielding piece 163, the semi-shielding piece 164, and the color filter 151 are disposed in the same layer. The alignment film 161 is integrally formed and then separately aligned in different regions to achieve synchronized processing of the light-shielding piece 163 and the semi-shielding piece 164.

In another embodiment, the anti-reflection layer 160 is disposed on the color filter layer 150. Adjacent color filters 151 of different colors in the color filter layer 150 are directly in contact with each other. A light-shielding piece 163 is disposed at the contact position, and a corresponding semi-shielding piece 164 is disposed in the white sub-pixel area.

### Embodiment 5

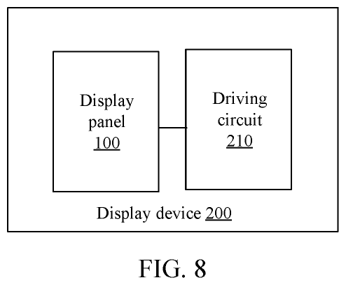

FIG. 8 is a schematic diagram of a display device according to a fifth embodiment of the present application. Referring to FIG. 8, this application discloses a display device. The display device 200 includes a driving circuit 210 and the display panel 100 described in any of the foregoing embodiments. The driving circuit 210 is used to drive the display panel 100 to display.

In this application, the alignment film 161 is used and the polarizing molecules 162 are arranged in the alignment film 161, and the polarizing molecules 162 are arranged in an oriented manner to absorb the incident light from the outside world and prevent external incident light from entering the display panel 100 and causing some of the film layers in the display panel 100 to reflect the incident light, causing problems such as glare. In addition, the present application may provide an anti-reflection layer 160 in a local area, and use the anti-reflection layer 160 to improve the phenomenon of ambient light reflection without reducing the brightness and display effect. The anti-reflection layer 160 of the present application is formed by an alignment film 161 and polarizing molecules 162, and has a simple structure, simple manufacturing process, and low cost. In particular, the manufacturing process of the alignment film 161 is mature, and there will be no problems such as film defects between the alignment film 161 and other film layers such as the color filter layer 150.

It should be noted that the inventive concept of the present application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing description is merely a further detailed description of the present application made with reference to some specific illustrative embodiments, and the specific implementations of the present application are not to be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. A display panel, comprising:
a substrate;
a light-emitting element layer, comprising a plurality of light-emitting elements, which are arranged in an array on the substrate;
a pixel defining layer, arranged on the substrate; wherein every two adjacent light-emitting elements are separated by the pixel defining layer;
an encapsulation layer, arranged on the plurality of light-emitting elements and the pixel defining layer;
a color filter layer, comprising a plurality of color filters arranged on the encapsulation layer; and
an anti-reflection layer, arranged on the encapsulation layer and used to block external light from entering an interior of the display panel;
wherein the anti-reflection layer comprises an alignment film and a plurality of polarizing molecules that are evenly distributed in the alignment film; wherein the plurality of polarizing molecules are aligned in mutually perpendicular orientations and/or in a unidirectional orientation in the alignment film.

2. The display panel as recited in claim 1, wherein the display panel comprises an opening region and a non-opening region; wherein the pixel defining layer is disposed in the non-opening region, and the light-emitting element layer is disposed in the opening region;
wherein the anti-reflection layer comprises a light-shielding piece disposed in the non-opening region corresponding to the pixel defining layer; wherein the plurality of polarizing molecules in the light-shielding piece are aligned in two mutually perpendicular orientations to be mutually perpendicular to each other to form a mutually perpendicular arrangement, and wherein the light-shielding piece is used for light-shielding.

3. The display panel as recited in claim 2, wherein the light-shielding piece and the plurality of color filters are disposed in a same layer, and wherein every two adjacent color filters are separated by the respective light-shielding piece.

4. The display panel as recited in claim 1, wherein the display panel comprises an opening region and a non-opening region; wherein the pixel defining layer is disposed in the non-opening region, and the light-emitting element layer is disposed in the opening region;
wherein the anti-reflection layer comprises a semi-shielding piece disposed corresponding to the opening region, wherein the plurality of polarizing molecules of the semi-shielding piece are aligned in a unidirectional orientation to form a unidirectionally aligned arrangement; wherein the semi-shielding piece is used to transmit part of an outgoing light and block an incident light from an outside of the display panel.

5. The display panel as recited in claim 4, wherein the plurality of light-emitting elements comprise a plurality of white light-emitting elements and a plurality of first light-emitting elements; wherein an orthographic projection of the semi-shielding piece on the substrate overlaps an orthographic projection of the respective white light-emitting element on the substrate; wherein the plurality of color filters are arranged in one-to-one correspondence with the plurality of first light-emitting elements;
wherein the plurality of first light-emitting elements comprise at least two light-emitting elements with different colors.

6. The display panel as recited in claim 1, wherein the display panel comprises an opening region and a non-opening region; wherein the pixel defining layer is disposed in the non-opening region, and the light-emitting element layer is disposed in the opening region;
wherein the anti-reflection layer comprises a light-shielding piece and a semi-shielding piece; wherein the light-shielding piece is arranged in the non-opening region corresponding to the pixel defining layer, and the light-shielding piece is uses a mutually perpendicularly aligned arrangement in which the plurality of polarizing molecules in the light-shielding piece are aligned in mutually perpendicular orientations; wherein the semi-shielding piece is arranged corresponding to the opening region, and the semi-shielding piece uses a unidirectionally aligned arrangement in which the plurality of polarizing molecules in the semi-shielding piece are aligned in a unidirectional orientation;
wherein the plurality of light-emitting elements comprises a plurality of white light-emitting elements and a plurality of first light-emitting elements; wherein an orthographic projection of the semi-shielding piece on the substrate overlaps an orthographic projection of the respective white light-emitting element on the substrate; and wherein the plurality of first light-emitting elements comprise at least two light-emitting elements with different colors.

7. The display panel as recited in claim 6, wherein the light-shielding piece and the semi-shielding piece are formed using a same manufacturing procedure;
wherein the light-shielding piece and the semi-shielding piece have an equal thickness;
wherein the light-shielding piece, the semi-shielding piece, and the color filter are disposed in a same layer.

8. The display panel as recited in claim 6, wherein the anti-reflection layer is disposed on the color filter layer.

9. The display panel as recited in claim 1, wherein the plurality of polarizing molecules in the alignment film has a concentration that is no greater than 20%.

10. The display panel as recited in claim 1, wherein the plurality of polarizing molecules are iodine dye molecules.

11. The display panel as recited in claim 6, wherein the color filter comprises a red filter, a green filter, and a blue filter; wherein the plurality of first light-emitting elements comprises a plurality of red light-emitting elements, a plurality of green light-emitting elements, and a plurality of blue light-emitting elements;
wherein the red filter is disposed corresponding to the respective red light-emitting element, the green filter is disposed corresponding to the respective green light-emitting element, and the blue filter is disposed corresponding to the respective blue light-emitting element.

12. The display panel as recited in claim 1, wherein the encapsulation layer comprises at least two inorganic encapsulation layers and an organic encapsulation layer disposed between the at least two inorganic encapsulation layers.

13. The display panel of claim 1, wherein the alignment film has a thickness of 100 nm.

14. The display panel as recited in claim 6, wherein the semi-shielding piece has an annular shape and is disposed around the respective color filter.

15. The display panel as recited in claim 14, wherein an area of the semi-shielding piece does not exceed one quarter of an area of the corresponding color filter.

16. A display device, comprising a driving circuit and a display panel, wherein the driving circuit is used to drive the display panel to display;
wherein the display panel comprises a substrate, a light-emitting element layer, a pixel defining layer, an encapsulation layer, a color filter layer, and an anti-reflection layer;
wherein the light-emitting element layer comprises a plurality of light-emitting elements, which are arranged in an array on the substrate; the pixel defining layer is disposed on the substrate, and wherein every two adjacent light-emitting elements are separated by the pixel defining layer; the encapsulation layer is disposed on the plurality of light-emitting elements and the pixel defining layer; the color filter layer comprises a plurality of color filters disposed on the encapsulation layer; the anti-reflection layer is disposed on the encapsulation layer to block external light from entering an interior of the display panel; wherein the anti-reflection layer comprises an alignment film and a plurality of polarizing molecules evenly distributed in the alignment film; wherein the polarizing molecules are aligned in mutually perpendicular orientations and/or in a unidirectional orientation in the alignment film.

17. The display device as recited in claim 16, wherein the display panel comprises an opening region and a non-opening region; wherein the pixel defining layer is disposed in the non-opening region, and the light-emitting element layer is disposed in the opening region;
wherein the anti-reflection layer comprises a light-shielding piece, which disposed in the non-opening region corresponding to the pixel defining layer; wherein the plurality of polarizing molecules in the light-shielding piece are aligned in two mutually perpendicular orientations to be mutually perpendicular to each other to form a mutually perpendicular arrangement, and wherein the light-shielding piece is used for light-shielding.

18. The display device as recited in claim 17, wherein the light-shielding piece and the color filter are disposed in a same layer, and wherein every two adjacent color filters are separated by the respective light-shielding piece.

19. The display device as recited in claim 16, wherein the display panel comprises an opening region and a non-opening region; wherein the pixel defining layer is disposed in the non-opening region, and the light-emitting element layer is disposed in the opening region; wherein the anti-reflection layer comprises a semi-shielding piece, which is disposed corresponding to the opening region; wherein the plurality of polarizing molecules in the semi-shielding piece are aligned in a unidirectional orientation to form a unidirectionally aligned arrangement; wherein the semi-shielding piece is used to transmit part of an outgoing light and block an incident light from an outside of the display panel.
